(19) United States
(12) Patent Application Publication
(10) Pub. No.: US 2006/0179385 A1
(43) Pub. Date: Aug. 10, 2006

(54) Context-sensitive user help in a software-based development environment

(75) Inventor: Georg Kreiner, Ammerthal (DE)

Correspondence Address: SIEMENS CORPORATION;INTELLECTUAL PROPERTY DEPARTMENT, 170 WOOD AVENUE, SOUTH, ISELIN, NJ, 08830, US

(73) Assignee: SIEMENS AKTIENGESELLSCHAFT

(21) Appl. No.: 11/348,791

(22) Filed: Feb. 7, 2006

(30) Foreign Application Priority Data
Feb. 9, 2005 (EP) 05002709.3

(51) Int. Cl. G01R 31/28; G06F 11/00

(52) U.S. Cl. 714/741

(57) ABSTRACT

The invention relates to a method, a system and a computer program product for provision of user information within a software-based development environment for designing circuits and/or systems constructed from functional units. In order to provide help which is context-sensitive and can be rapidly grasped by a user, the following procedural steps are proposed: Recognition of a functional unit selected by user, Presentation of a demonstration application within which the selected functional unit is contained, Simulation of the demonstration application and Visualization of the simulation results.

### CROSS REFERENCE TO RELATED APPLICATIONS

This application claims priority to the European Application No. 05002709.3, filed Feb. 9, 2005 which is incorporated by reference herein in its entirety.

### FIELD OF INVENTION

The invention relates to a method, a computer program product and a system for provision of user information within a software-based development environment for designing circuits and/or systems constructed from functional units.

### BACKGROUND OF INVENTION

These types of development environments are for example circuit simulation programs, in which electrical functional units (e.g. resistors, capacitors . . . ), electronic (e.g. diodes, MOSFETs . . . ), logical (e.g. AND gates, Inverters . . . ) or also pneumatic (e.g. valves . . . ) functional units can be combined in a circuit design by a user. The resulting circuit can subsequently be simulated in order to check a desired functionality.

### SUMMARY OF INVENTION

In a system simulation complex systems are frequently constructed from individual subsystems. The invention can also be used in such cases to provide a user with information about the individual functional units—the subsystems—when designing an overall system.

A further area of application to mention is graphics-based programming environments, in which in particular controller programs are generated with the aid of a graphical user interface by connecting together functional units.

Functional units provided by a development environment can under some circumstances exhibit a very complex functionality. Thus the appropriate help texts are generally provided by the development environment for the available function blocks. An object of the invention is to provide, in a software-based development environment, a context-sensitive help which can be rapidly grasped by the user.

This object is achieved by a method for provision of user information within a software-based development environment for designing circuits and/or systems constructed from functional units with the following procedural steps:

Recognition of a functional unit selected by a user,

Presentation of a demonstration application within which the selected functional unit is contained,

Simulation of the demonstration application and

Visualization of the simulation results.

Furthermore the object is achieved by a computer program product for executing this type of method.

Furthermore this object is achieved by a system for provision of user information with a memory for a software-based development environment for the design of circuit and/or systems constructed from functional units, with the system featuring

Means for recognition of a functional unit selected by a user,

Means for presentation of a demonstration application within which the selected functional unit is contained,

Means for simulation of the demonstration application and

Means for visualization of the simulation results.

The invention is based on the knowledge that it is frequently difficult to describe complex functions for a user in an easily-understandable and brief form. Thus many users tend, when working in the development environment, to prefer to test out new functions which are unknown to them rather than reading long-winded descriptive texts about these functions.

In the inventive method the user has the opportunity, with reference to a demonstration application, to try out the functionality of a selected functional unit himself. This can for example be realized within the development environment in the following way. If the user selects a functional unit within his user interface, he then has the opportunity, by a clicking with the right mouse button for example, of opening a demonstration application within which the selected functional unit is shown as the central element. The user can modify the demonstration application and subsequently simulate it, with the results of the simulation being visualized. In this manner the user learns almost in a form of play about the function of the component which he has selected. It is not necessary to read a long document in this case.

For example this type of software-based development environment is provided for the design of the electrical, electronic and/or logical circuits. The programs involved here can for example be circuit simulation programs. Within these circuit simulation programs a user can, within a graphical user interface, create an electrical, electronic and/or logical circuit diagram in which he connects the corresponding functional units to each other. The functional units involved are for example electrical or electronic components or logical function blocks such as an AND or an OR gate or an inverter. The circuit created in this way can then be simulated and the results of the simulation are presented on a screen for the user.

Alternatively the software-based development environment can be provided for the design of an open-loop or closed-loop controller. In the design of closed-loop control circuits function blocks which represent a specific transmission function are connected to each other. An explanation of a selected function block will be given to the user in the form of a demonstration block diagram in which the function block plays a central role. The demonstration block diagram can be simulated by the user. Inputs and outputs of the function blocks within the block diagram can be visualized so that the user can understand the functionality of the selected block by trying it out.

In an advantageous embodiment of the inventive method a dialog field is opened before the start of the simulation within which the user can modify the value of at least one parameter which has an influence on the simulation results. In this manner the user is able to influence the execution sequence of the simulation himself. He can actively test out the functionalities of the selected function block. It is especially advantageous for this if the parameter influences the behavior of the selected functional unit.

Expediently the selected functional unit is connected via inputs and/or outputs to further functional units in the demonstration application, with the states of the inputs and/or outputs being visualized during and/or after the simulation. It is conceivable for example that during the simulation a window opens within which the results of the simulation are entered over time. For the simulation of an electrical or electronic circuit it would be conceivable here for example that the simulation results involved would be potentials at the inputs and outputs of the selected functional unit.

To ensure that the user has especially great freedom when working with the demonstration application an expedient execution of the invention is characterized by the demonstration application being able to be modified by the user especially by adding and/or removing the functional units and/or by changing the states at inputs of the functional units. If the demonstration application involved is a logical circuit for example any function blocks can be added or removed by the user to enable conclusions to be drawn about the function of a selected function block.

In addition to the explanation of the functionality of the selected functional unit in the form of a demonstration application able to be influenced by the user, it can be sensible, for the presentation of the demonstration application and/or in the visualization of simulation results, for a text-based and/or graphics-based explanation for the selected functional unit to be displayed. This type of text-based and/or graphics-based explanation does not have to be as detailed as would be the case in a conventional development environment. The additional explanation merely serves to explain functionalities of the selected block which cannot be communicated by the presentation of the simulation.

The selected functional unit can either be an inherent component of the development environment or a user-defined functional unit which is especially constructed from further functional units which are inherent components of the development environment. It is thus also conceivable and is part of the invention for a user to construct a functional unit himself and insert it into the development environment as a component. He can also develop a demonstration application for this component and link it into the development environment on the basis of which a further user can be informed about the functionality of this module.

### BRIEF DESCRIPTION OF THE DRAWINGS

The invention is described and explained in more detail below on the basis of the exemplary embodiments shown in the Figures. The figures show:

FIG. 1 a user interface of a development environment in which the inventive method is used,

FIG. 2 a further user interface for creating a development environment in which the method in accordance with the invention is used and

FIG. 3 an inventive embodiment of a system for providing user information within a software-based development environment.

### DETAILED DESCRIPTION OF INVENTION

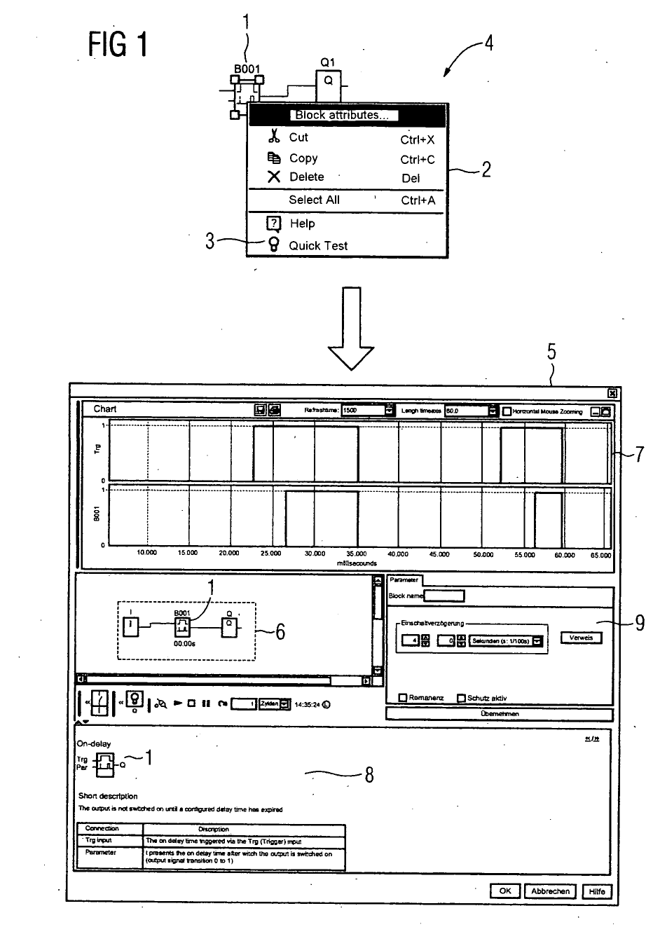

FIG. 1 shows a user interface 4 of a development environment in which the method in accordance with the invention is used. The development environment shown is a graphical programming environment within which the user can define a logical circuit. The logical circuit consists of individual functional units, also referred to as function blocks below, which the user can pull-down from a function strip on the screen and wire to each other. The individual function blocks 1 represent elements of a logical circuit, e.g. an AND gate, an OR gate or also an inverter. A circuit constructed in this way can first be simulated by the user within the development environment in order to check the actual functionality of circuit. Subsequently the user, based on the logical circuit, can have a control code generated automatically which can be loaded into the corresponding controller.

Within the graphical user interface 4 the user selects a functional unit 1, in the example a delay element, with the mouse pointer. By clicking on the right mouse button the user opens a menu 2 for the selected functional unit 1. Within the menu 2 there is the button 3 which when pressed opens a further window 5. Within the further window 5 a demonstration application 6 embodied as a logical circuit is displayed in which the functional unit 1 selected by the user forms a central component. The demonstration application 6 can then be simulated by the user. In order to be able to exert influence on the simulation, the user has the opportunity, in a parameter field 9, to modify parameters which influence the simulation. In this manner the user has the opportunity, by variation of the parameters, of getting to know the functionalities of the selected unit 1, the delay element, by trying them out. In addition the user can even modify the demonstration application 6 by for example placing further functional units in the further window 5, with the mouse for example and connecting these to the demonstration application 6. Furthermore he can also influence the input states of the function blocks contained in the demonstration application 6.

As soon as the user starts the simulation of the demonstration application 6 the simulation results 7 are displayed in an upper area of the window 5. Here the states of the inputs and outputs of the selected functional unit 1 over time are illustrated.

In addition to the presentation of the demonstration circuit 6 and the simulation results 7 within the window 5, an explanatory text 8 about the selected functional unit 1 is shown in a lower area of the window 5. This explanatory text 8 is kept very short since the user can find out about the essential features of the selected functional unit 1 in the inventive method by trying them out. This means that the user is not expected to spend a lot of time reading longer documentation.

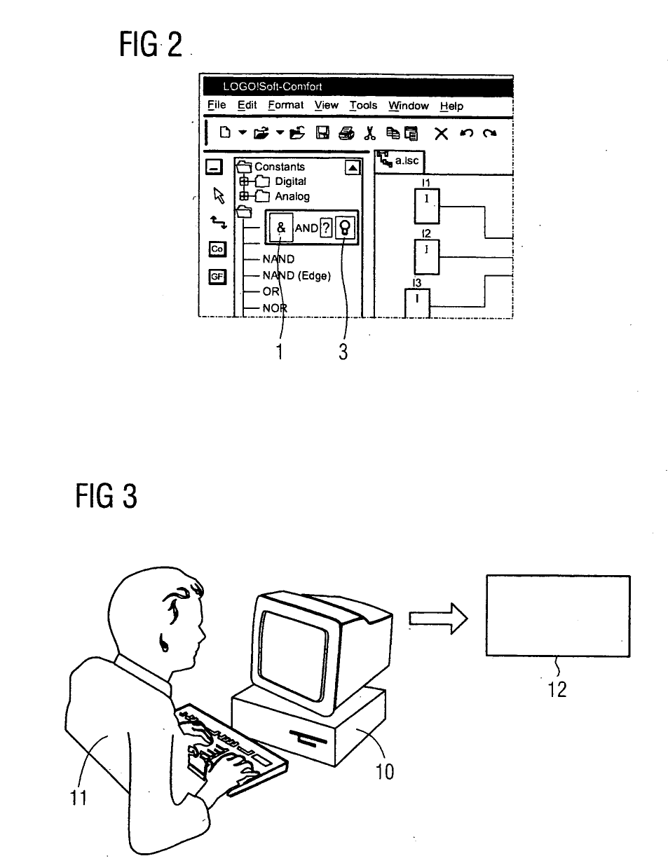

FIG. 2 shows a further user interface for creating a development environment in which the inventive method is used. In the embodiment shown here functional units 1, from which logical circuits can be generated, are stored in a tree structure. The functional units 1 in their turn represent logical functions which can be linked together to form a circuit diagram. In the example shown a user marks a functional unit 1 within the tree structure, especially using the mouse pointer, in order to integrate it into a logical circuit. In this case a window opens which shows him that the selected functional unit represents an AND gate. Furthermore a button is displayed with which a demonstration application can be opened up, on the basis of which the function of the AND gate will be demonstrated.

FIG. 3 shows an inventive embodiment of a system for provision of user information within a software-based development environment. The system features a data processing installation 10 on which a development environment for designing circuits constructed from functional units is installed. With the aid of this development environment a user 11 can plan a project for a control program on the data processing installation 10 which can then be loaded onto a Programmable Logic Controller (PLC) 12. The control program is implemented within the development environment in the form of a block diagram.

A block diagram of this type is constructed from a plurality of function blocks. To explain to the user 11 the in some cases very complex functionality of the individual blocks, a computer program for providing the corresponding user information is installed on the data processing installation 10. The computer program enables the user 11 to learn the functionality of the individual blocks by trying it out. To this end the computer programmer makes available a method which like the method described for FIG. 1, provides a demonstration application for each functional unit of the program on the basis of which the user can learn the function of the individual blocks by trying it out.

After the user 11 at the data processing installation 10 has drafted a block diagram for controlling a system, this can be simulated on the data processing installation 10 to check the correct functionality of the program. Subsequently a corresponding controller program can be generated from the block diagram on the data processing installation which is subsequently loaded onto the PLC 12.

The present invention is not intended to be limited to the exemplary embodiments shown here. Instead further embodiments are conceivable and are included in the invention, provided the basic idea that the user 11 is provided with user information for functional units in the form of a demonstration application modifier built by the user 11 is retained. The method proposed in accordance with the invention is not only suitable for use within a programming environment. The method can also be employed in pure simulation programs. Examples of this are circuit and system-simulation environments in which a user constructs an electrical circuit diagram or a closed-loop control block diagram in the form of individual functional units.

1.-21. (canceled)

22. A method of providing user information within a software-based development environment for designing circuits or systems, the system having a plurality of functional units, the method comprising:
selecting a functional unit by a user;
recognition the selected functional unit;
displaying a demonstration application having the selected functional unit;
simulating the demonstration application; and
visualizing simulation results of the simulated demonstration application.

23. The method in accordance with claim 22, further comprising opening a dialog window before starting the simulation, the dialog window configured to receive from the user a parameter input related to modify at least one parameter having an influence on the simulation results.

24. The method in accordance with claim 23, wherein a behavior of the selected functional unit is based on the parameter input.

25. The method in accordance with claim 22, wherein the selected functional unit is connected to other functional units via inputs or outputs within the demonstration application, current states of the inputs or outputs visualized during and/or after the simulation.

26. The method in accordance with claim 25, wherein the demonstration application is configured to be modified by the user.

27. The method in accordance with claim 26, further comprising adding or removing functional units to respectively from the demonstration application or changing the current states of the inputs or outputs, by the user.

28. The method in accordance with claim 22, further comprising displaying a text-based or graphics-based explanation of the selected functional unit while displaying the demonstration application or while visualizing the simulation results.

29. The method in accordance with claim 22, wherein the selected functional unit is an inherent component of the development environment.

30. The method in accordance with claim 22, wherein the selected functional unit is a user-defined functional unit including other functional units which are inherent components of the development environment.

31. A computer program for providing user information within a software-based development environment for designing circuits or systems, the system having a plurality of functional units, the computer program comprising software modules having software code configured and programmed to:
accept from a user a user input for selecting a functional unit;
recognize the selected functional unit;
display a demonstration application having the selected functional unit;
simulate the demonstration application; and
visualize simulation results of the simulated demonstration application.

32. A system for providing user information, comprising:
a memory having a software-based development environment for designing circuits or systems including a plurality of functional units;
a detecting unit for detecting a functional unit selected by a user;
a display device for displaying a demonstration application having the selected functional unit;
a simulator unit for simulating the demonstration application; and
a visualization device for visualizing simulation results of the simulated demonstration application.

33. The system in accordance with claim 32, wherein the system is configured to open a dialog window before starting the simulation, the dialog window configured to receive from the user a parameter input related to modify at least one parameter having an influence on the simulation results.

34. The system in accordance with claim 33, wherein a behavior of the selected functional unit is based on the parameter input.

35. The system in accordance with claim 32, wherein the selected functional unit is connected to other functional units via inputs or outputs within the demonstration application, current states of the inputs or outputs visualized during and/or after the simulation.

36. The system in accordance with claim 35, wherein the demonstration application is configured to be modified by the user.

37. The system in accordance with claim 36, wherein the modification includes adding or removing functional units to respectively from the demonstration application or changing the current states of the inputs or outputs.

38. The system in accordance with claim 32, wherein a text-based or graphics-based explanation of the selected functional unit is displayed while displaying the demonstration application or while visualizing the simulation results.

39. The system in accordance with claim 32, wherein the selected functional unit as an inherent component of the development environment.

40. The system in accordance with claim 32, wherein the selected functional unit is a user-defined functional unit including other functional units which are inherent components of the development environment.
